(19) United States
(12) Patent Application Publication
(10) Pub. No.: US 2025/0338778 A1
(43) Pub. Date: Oct. 30, 2025

(54) SEMICONDUCTOR DEVICE

(71) Applicant: UNITED MICROELECTRONICS CORP., Hsin-Chu City (TW)

(72) Inventors: Hui-Lin Wang, Taipei City (TW); Che-Wei Chang, Taichung City (TW); Ching-Hua Hsu, Kaohsiung City (TW); Chen-Yi Weng, New Taipei City (TW)

(73) Assignee: UNITED MICROELECTRONICS CORP., Hsin-Chu City (TW)

(21) Appl. No.: 18/749,637

(22) Filed: Jun. 21, 2024

(30) Foreign Application Priority Data
Apr. 29, 2024 (TW) 113115896

(51) Int. Cl. H10N 50/80; H10B 61/00; H10N 50/01; H10N 50/10

(52) U.S. Cl. CPC H10N 50/80; H10B 61/00; H10N 50/01; H10N 50/10

(57) ABSTRACT

A magnetoresistive random access memory (MRAM) device includes an inter-metal dielectric (IMD) layer on the substrate, a first metal interconnection and a second metal interconnection in the IMD layer, a bottom electrode (BE) on the IMD layer, a spin orbit torque (SOT) layer on the BE, a magnetic tunneling junction (MTJ) on the SOT layer, and a top electrode (TE) on the MTJ. Preferably, a top surface of the TE includes a curve.

### BACKGROUND OF THE INVENTION

### 1. Field of the Invention

The invention relates to a semiconductor device, and more particularly to a magnetoresistive random access memory (MRAM).

### 2. Description of the Prior Art

Magnetoresistance (MR) effect has been known as a kind of effect caused by altering the resistance of a material through variation of outside magnetic field. The physical definition of such effect is defined as a variation in resistance obtained by dividing a difference in resistance under no magnetic interference by the original resistance. Currently, MR effect has been successfully utilized in production of hard disks thereby having important commercial values. Moreover, the characterization of utilizing GMR materials to generate different resistance under different magnetized states could also be used to fabricate MRAM devices, which typically has the advantage of keeping stored data even when the device is not connected to an electrical source.

The aforementioned MR effect has also been used in magnetic field sensor areas including but not limited to for example electronic compass components used in global positioning system (GPS) of cellular phones for providing information regarding moving location to users. Currently, various magnetic field sensor technologies such as anisotropic magnetoresistance (AMR) sensors, GMR sensors, magnetic tunneling junction (MTJ) sensors have been widely developed in the market. Nevertheless, most of these products still pose numerous shortcomings such as high chip area, high cost, high power consumption, limited sensibility, and easily affected by temperature variation and how to come up with an improved device to resolve these issues has become an important task in this field.

### SUMMARY OF THE INVENTION

According to an embodiment of the present invention, a magnetoresistive random access memory (MRAM) device includes an inter-metal dielectric (IMD) layer on the substrate, a first metal interconnection and a second metal interconnection in the IMD layer, a bottom electrode (BE) on the IMD layer, a spin orbit torque (SOT) layer on the BE, a magnetic tunneling junction (MTJ) on the SOT layer, and a top electrode (TE) on the MTJ. Preferably, a top surface of the TE includes a curve.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate a method for fabricating a MRAM device according to an embodiment of the present invention.

### DETAILED DESCRIPTION

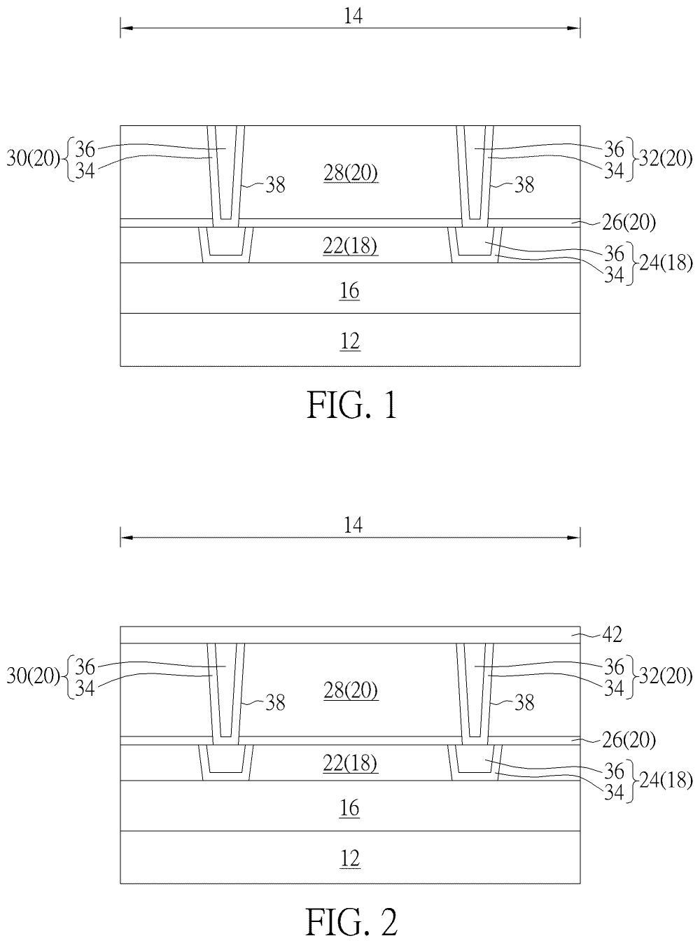

Referring to FIGS. 1-7, FIGS. 1-7 illustrate a method for fabricating a semiconductor device, or more specifically a MRAM device according to an embodiment of the present invention. As shown in FIG. 1, a substrate 12 made of semiconductor material is first provided, in which the semiconductor material could be selected from the group consisting of silicon (Si), germanium (Ge), Si—Ge compounds, silicon carbide (SiC), and gallium arsenide (GaAs), and a MRAM region 14 and a logic region (not shown) are defined on the substrate 12.

Active devices such as metal-oxide semiconductor (MOS) transistors, passive devices, conductive layers, and interlayer dielectric (ILD) layer 16 could also be formed on top of the substrate 12. More specifically, planar MOS transistors or non-planar (such as FinFETs) MOS transistors could be formed on the substrate 12, in which the MOS transistors could include transistor elements such as gate structures (for example metal gates) and source/drain region, spacer, epitaxial layer, and contact etch stop layer (CESL). The ILD layer 16 could be formed on the substrate 12 to cover the MOS transistors, and a plurality of contact plugs could be formed in the ILD layer 16 to electrically connect to the gate structure and/or source/drain region of MOS transistors. Since the fabrication of planar or non-planar transistors and ILD layer is well known to those skilled in the art, the details of which are not explained herein for the sake of brevity.

Next, metal interconnect structures 18, 20 are sequentially formed on the ILD layer 16 to electrically connect the aforementioned contact plugs, in which the metal interconnect structure 18 includes an inter-metal dielectric (IMD) layer 22 and metal interconnections 24 embedded in the IMD layer 22, and the metal interconnect structure 20 includes a stop layer 26, an IMD layer 28, and metal interconnections 30, 32 embedded in the stop layer 26 and the IMD layer 28.

In this embodiment, each of the metal interconnections 24 from the metal interconnect structure 18 preferably includes a trench conductor and each of the metal interconnections 30, 32 from the metal interconnect structure 20 includes a via conductor. Preferably, each of the metal interconnections 24, 30, 32 from the metal interconnect structures 18, 20 could be embedded within the IMD layers 22, 28 and/or stop layer 26 according to a single damascene process or dual damascene process. For instance, each of the metal interconnections 24, 30, 32 could further include a barrier layer 34 and a metal layer 36, in which the barrier layer 34 could be selected from the group consisting of titanium (Ti), titanium nitride (TiN), tantalum (Ta), and tantalum nitride (TaN) and the metal layer 36 could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. In this embodiment, the metal layers 36 in the metal interconnections 24 are preferably made of copper, the metal layers 36 in the metal interconnections 30, 32 are preferably made of tungsten, the IMD layers 22, 28 are preferably made of silicon oxide or ultra low-k (ULK) dielectric layer, and the stop layers 26 is preferably made of nitrogen doped carbide (NDC), silicon nitride, silicon carbon nitride (SiCN), or combination thereof.

Next, as shown in FIG. 2, a bottom electrode (BE) layer 42 is formed on the IMD layer 28 and a planarizing process such as chemical mechanical polishing (CMP) process is conducted to remove part of the BE layer 42 so that the thickness of the BE layer 42 is slightly reduced but still covering the entire top surface of the IMD layer 28. In this embodiment, the BE layer 42 preferably includes metal or metal nitride such as but not limited to for example tantalum (Ta) or tantalum nitride (TaN).

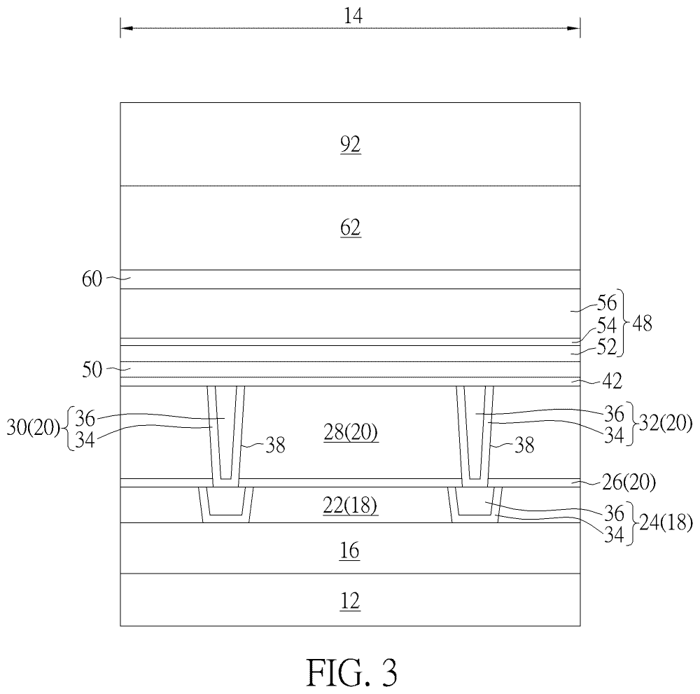

Next, as shown in FIG. 3, a spin orbit torque (SOT) layer 50 is formed on the surface of the BE layer 42, a MTJ stack 48 is formed on the SOT layer 50, and then a cap layer 60, a top electrode (TE) 62, and a hard mask 92 are formed on the MTJ stack 48.

In this embodiment, the formation of the MTJ stack 48 could be accomplished by sequentially depositing a free layer 52, a barrier layer 54, and a pinned layer 56 on the SOT layer 50. Preferably, the free layer 52 could be made of ferromagnetic material including but not limited to for example iron, cobalt, nickel, or alloys thereof such as cobalt-iron-boron (CoFeB), in which the magnetized direction of the free layer 52 could be altered freely depending on the influence of outside magnetic field. The barrier layer 54 could be made of insulating material including but not limited to for example oxides such as aluminum oxide (AlOₓ) or magnesium oxide (MgO). The pinned layer 56 could be made of antiferromagnetic (AFM) material including but not limited to for example ferromanganese (FeMn), platinum manganese (PtMn), iridium manganese (IrMn), nickel oxide (NiO), or combination thereof, in which the pinned layer 56 is formed to fix or limit the direction of magnetic moment of adjacent layers. It should be noted that since the present embodiment pertains to fabricating a SOT MRAM device, the free layer 52 is preferably disposed on the bottommost layer to contact the SOT layer 50 directly.

Preferably, the SOT layer 50 is serving as a channel for the MRAM device as the SOT layer 50 could include metals such as tantalum (Ta), tungsten (W), platinum (Pt), or hafnium (Hf) and/or topological insulator such as bismuth selenide (BiₓSe₁₋ₓ). The cap layer 60 preferably includes metal such as Ta and the TE 62 preferably includes conductive material such as metal or metal nitride, in which metal could include Ti whereas metal nitride could include TiN. Nevertheless, the cap layer 60 or TE 62 could all include conductive or dielectric material including but not limited to for example Ta, TaN, Ti, TiN, Pt, Cu, Au, Al, or combination thereof. The hard mask 92 could include dielectric material such as silicon oxide, but not limited thereto.

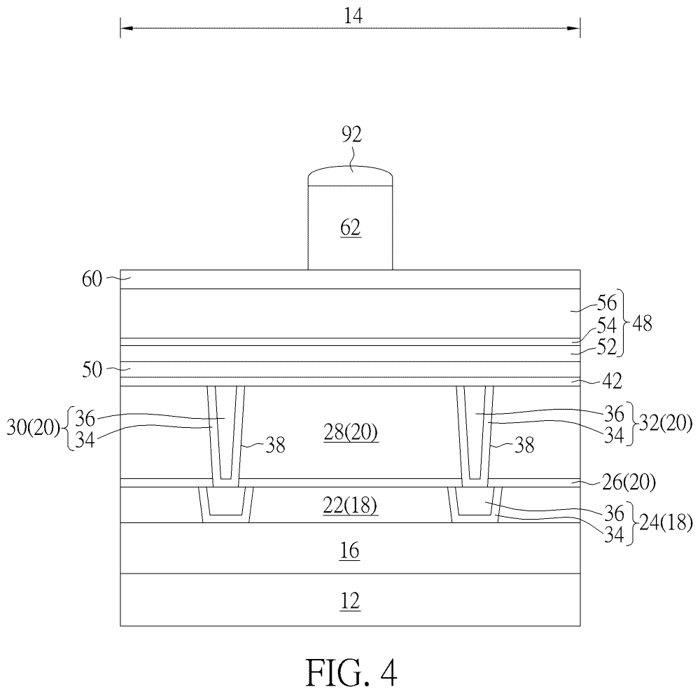

Next, as shown in FIG. 4, an etching process such as a reactive ion etching (RIE) process is conducted by using a patterned mask such as patterned resist (not shown) as mask to remove part of the hard mask 92 and part of the TE 62 for forming a patterned hard mask 92 and patterned TE 62. It should be noted that after patterning the hard mask 92 at this stage, the remaining hard mask 92 preferably has a curved top surface or more specifically a planar top surface with two curves between two sidewalls of the hard mask 92 and the planar top surface of the hard mask 92.

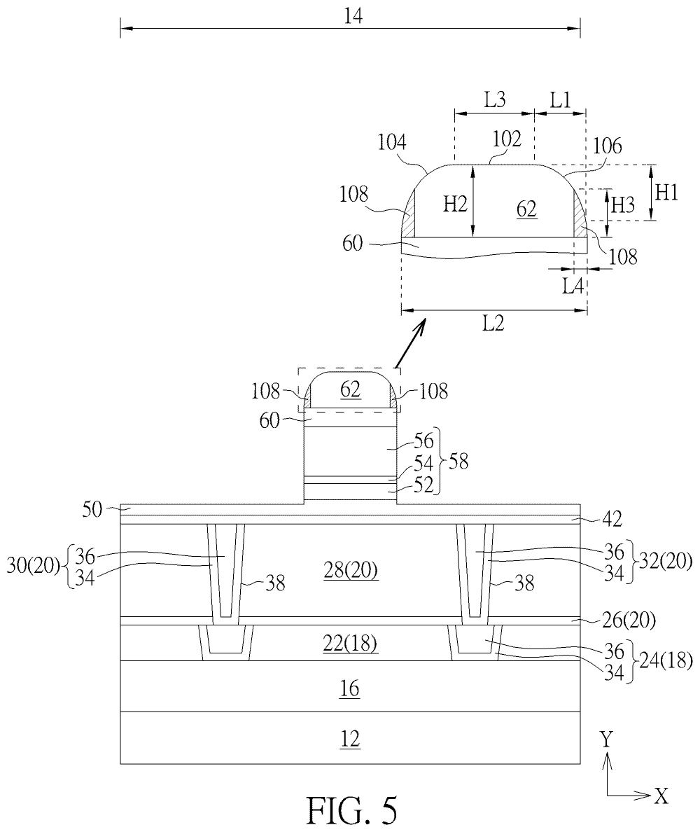

Next, as shown in FIG. 5, after removing the patterned hard mask 92, one or more etching process such as a RIE or ion beam etching (IBE) process is conducted by using the patterned TE 62 as mask to remove part of the cap layer 60, part of the MTJ stack 48, and even part of the SOT layer 50 for forming a MTJ 58 on the SOT layer 50.

It should be noted that after the etching process is conducted, the TE 62 preferably includes a planar surface 102 extending along a first direction such as X-direction, a curve 104 connected to one side such as left side of the planar surface 102, and another curve 106 connected to another side such as right side of the planar surface 102, in which each of the curves 104, 106 includes a curve concave downward. Specifically, a height Hl is measured from a top surface of the TE 62 to a bottom of the left side curve 104 or a bottom of the right side curve 106, a height H2 is measured from the top surface of the TE 62 to the bottom surface of the TE 62, a length L1 is measured from an edge of the planar surface 102 of the top surface of TE 62 to a vertical sidewall of the TE 62, the bottom surface of the TE 62 includes a length L2, and the planar surface 102 of the top surface of TE 62 includes a length L3.

According to a preferred embodiment of the present invention, the height Hl is between 10-30 nm, the height H2 is between 30-50 nm, the length L1 is between 25-35 nm, and the length L2 is between 75-115 nm, in which a ratio of H1/H2 is approximately 03-0.6, a ratio of L1/L2 is approximately 0.2-0.5, and a ratio of L3/L2 is approximately 0.5-0.8. In other words, the width or length L3 of the planar surface 102 of the top surface of TE 62 is greater than half of the entire width or length L2 of the bottom surface of TE 62 and less than 80% of the entire width or length L2 of the bottom surface of TE 62.

It should also be noted that the during the process when the aforementioned RIE or IBE process were conducted for patterning the MTJ stack 48 to form the MTJ 58, part of metal ions from the MTJ 58 could be sputtered upward to form doped regions 108 on curved sidewalls and vertical sidewalls of the TE 62. Preferably, the doped regions 108 could include materials such as TiN from the TE 62 or metals such as iron (Fe), cobalt (Co), nickel (Ni), or alloy thereof from the MTJ 58. In contrast to top electrode (TE) sidewalls having planar and inclined sidewalls or even completely planar sidewalls so that height of doped regions formed by splattering of metal ions is substantially equal to the height of the entire TE in conventional art, the formation of the above curves 104, 106 on sidewalls of the TE 62 in present invention effectively lowers the height H3 of the doped regions 108 to be less than 80% or even 70% of the height H2 of the entire TE 62. In this embodiment, the doped region 108 includes a width L4 extending along the X-direction and a height H3 extending along the Y-direction, in which the ratio of L4/L2 is between 0.02-0.15 while the ratio of H3/H2 is between 0.3-0.7.

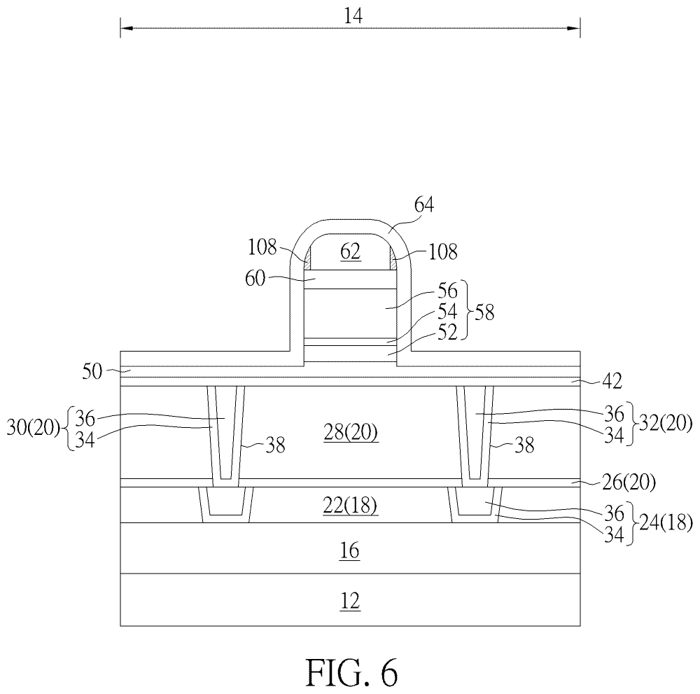

Next, as shown in FIG. 6, a cap layer 64 is formed on the surface of the TE 62, MTJ 58, and SOT layer 50. In this embodiment, the SOT layer 50 could be etched or not etched during the patterning of the MTJ stack 48 so that after the MTJ 58 is formed, the top surface of the SOT layer 50 directly under the MTJ 58 could be even with or slightly higher than the top surface of the SOT layer 50 adjacent two sides of the MTJ 58, which are all within the scope of the present invention. Preferably, the cap layer 64 is made of nitrogen doped carbide (NDC), silicon nitride (SIN), silicon carbon nitride (SiCN), or combination thereof and most preferably made of SiN.

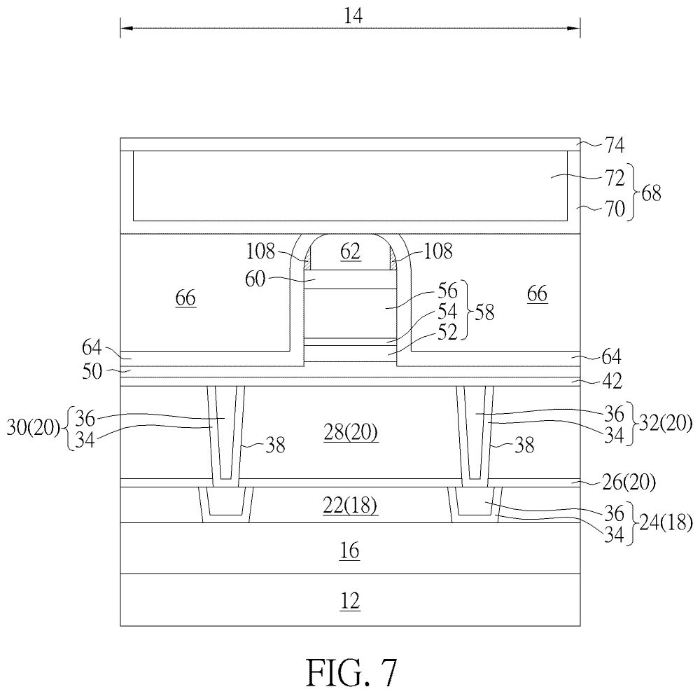

Next, as shown in FIG. 7, an IMD layer 66 is formed on the cap layer 64 and one or more photo-etching process is conducted to remove part of the IMD layer 66 and part of the cap layer 64 to form at least a contact hole (not shown) exposing the TE 62. Next, conductive materials are deposited into the contact hole and planarizing process such as CMP is conducted to form metal interconnection 68 connecting the TE 62 underneath, and another stop layer 74 is formed on the surface of the metal interconnection 68 thereafter. Similar to the aforementioned metal interconnections 24, the metal interconnection 68 could be embedded within the IMD layer 66 according to a single damascene process or dual damascene process. For instance, the metal interconnection 68 could further include a barrier layer 70 and a metal layer 72, in which the barrier layer 70 could be selected from the group consisting of titanium (Ti), titanium nitride (TiN), tantalum (Ta), and tantalum nitride (TaN) and the metal layer 72 could be selected from the group consisting of tungsten (W), copper (Cu), aluminum (Al), titanium aluminide (TiAl), and cobalt tungsten phosphide (CoWP).

In this embodiment, the IMD layer 66 preferably include an ultra low-k (ULK) dielectric layer including but not limited to for example porous material or silicon oxycarbide (SiOC) and the stop layer 74 preferably includes nitrogen doped carbide (NDC), silicon nitride (SIN), silicon carbon nitride (SiCN), or combination thereof and most preferably includes SiN. This completes the fabrication of a semiconductor device according to an embodiment of the present invention.

Overall, the present invention discloses a SOT MRAM device, which preferably adjusts the etching parameters during patterning of the MTJ stack for forming a TE 62 with a reverse saucepan or frying pan shape cross-section, in which the top surface of the TE includes a planar surface 102 extending along a first direction such as X-direction, a curve 104 connected to one side such as left side of the planar surface 102, and another curve 106 connected to another side such as right side of the planar surface 102. By shaping the top surface of the top electrode to have the aforementioned curvy profile, it would be desirable to effective improve the efficiency of IBE process and reduce amount of residues adhered on sidewalls of the TE thereby increasing stability of the device.

Those skilled in the art will readily observe that numerous modifications and alterations of the device and method may be made while retaining the teachings of the invention. Accordingly. the above disclosure should be construed as limited only by the metes and bounds of the appended claims.

What is claimed is:

1. A magnetoresistive random access memory (MRAM) device, comprising:
a spin orbit torque (SOT) layer on a substrate;
a magnetic tunneling junction (MTJ) on the SOT layer; and
a top electrode (TE) on the MTJ, wherein a top surface of the TE comprises a curve.

2. The MRAM device of claim 1, further comprising:
an inter-metal dielectric (IMD) layer on a substrate;
a first metal interconnection and a second metal interconnection in the IMD layer;
a bottom electrode (BE) on the IMD layer; and
the SOT layer on the BE.

3. The MRAM device of claim 1, wherein the MTJ comprises:
a free layer on the SOT layer;
a barrier layer on the free layer; and
a pinned layer on the barrier layer.

4. The MRAM device of claim 1, wherein the top surface of the TE comprises:
a planar surface extending along a first direction;
a first curve connected to one side of the planar surface; and
a second curve connected to another side of the planar surface.

5. The MRAM device of claim 4, wherein the first curve comprises a curve concave downward.

6. The MRAM device of claim 4, wherein the second curve comprises a curve concave downward.
